(19) United States
(12) Patent Application Publication
(10) Pub. No.: US 2012/0167945 A1
(43) Pub. Date: Jul. 5, 2012

(54) PHOTOVOLTAIC DEVICES HAVING SHAPED CONCENTRATOR MEMBERS

(75) Inventors: Daniel SHUGAR, Fremont, CA (US); Abhay Maheshwari, Fremont, CA (US)

(73) Assignee: Solaria Corporation, Fremont, CA (US)

(21) Appl. No.: 12/982,077

(22) Filed: Dec. 30, 2010

(51) Int. Cl. H01L 31/052; H01L 31/18

(52) U.S. Cl. 136/246; 29/825

(57) ABSTRACT

Photovoltaic devices having shaped concentrator members. The present invention is directed to solar energies. More specifically, various embodiments of the present invention provide a shaped concentrator member that is used as a part of concentrated solar panel. The shape concentrator member includes semi-cylindrically shaped concentrator elements arranged and spaced in parallel to one another. At the edges of the shaped concentrator member, there are flat edge regions that include flat surfaces. There are other embodiments as well.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH AND DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention is directed to solar energies.

As the population of the world has increased, industrial expansion has led to a corresponding increased consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

In addition to oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many desirable characteristics; it is renewable, clean, abundant, and often widespread. Certain technologies developed often capture solar energy, concentrate it, store it, and convert it into other useful forms of energy.

Solar panels have been developed to convert sunlight into energy. For example, solar thermal panels are used to convert electromagnetic radiation from the sun into thermal energy for heating homes, running certain industrial processes, or driving high-grade turbines to generate electricity. As another example, solar photovoltaic panels are used to convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successfully for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of costly photovoltaic silicon bearing wafer materials, which are often difficult to manufacture efficiently on a large scale, and sources can be limited.

Concentrated solar panel designs reduces the amount of photovoltaic material needed for manufacturing solar panels. If not implemented efficiently, the costs saving from photovoltaic material can be offset by manufacturing costs. Therefore, it is desirable to have novel system and method for manufacturing solar panels.

### BRIEF SUMMARY OF THE INVENTION

The present invention is directed to solar energies. More specifically, various embodiments of the present invention provide a shaped concentrator member that is used as a part of concentrated solar panel. The shaped concentrator member includes semi-cylindrically shaped concentrator elements arranged and spaced in parallel to one another. At the edges of the shaped concentrator member, there are flat edge regions that include flat surfaces. In certain embodiments, the shaped concentrator member is used as a part of frameless solar module. There are other embodiments as well.

According to an embodiment, the present invention provides a solar panel device. The device includes a substrate member. The device also includes a plurality of photovoltaic strips overlaying the substrate member. The plurality of photovoltaic strips is aligned according to a predefined pattern. The device further includes a bus electrically coupling two or more photovoltaic strips. The device also includes a concentrator member comprising a first surface and a second surface. The first surface and the second surface are positioned on opposite sides of the concentrator member. The first surface is substantially flat. The concentrator member comprises a thickness of at least 4 mm between the first surface and the second surface. The second surface comprises a concentrator region and a two edge regions. The concentrator region is positioned between the two edge regions. The concentrator region includes a plurality of concentrator strips. The plurality of concentrator strips is aligned according to the predefined pattern. Each of the concentrator strip is characterized by a substantially semi-cylindrical shape and a radius of less than 5 mm. Each of the concentrator strip is positioned over a predetermined photovoltaic strip. The two edge regions comprise a first edge member and a second edge member. The first edge member includes a curved region connected to a first concentrator strip. The first edge member further comprises a flat region of at least 6 mm.

The solar panel can be implemented in various ways. In an embodiment, the concentrator strips each comprises a top flat region that is leveled against the flat region of the first concentrator strip. In an embodiment, the concentrator member is characterized by a substantially square shape. In an embodiment, the concentrator member is free from sharp edges. In an embodiment, the plurality of photovoltaic strips is secured to the substrate member by a bonding material.

In an embodiment, the device further includes a frame member coupled to the flat region of the first edge member.

In an embodiment, the concentrator member comprises at least 150 concentrator strips.

In an embodiment, each of the concentrator strip is aligned to direct light to at least two photovoltaic strips.

In an embodiment, the concentrator strips are evenly spaced.

In an embodiment, the device further comprises an epoxy material.

In an embodiment, the concentrator member comprises glass material.

In an embodiment, the concentrator member comprises a transparent material characterized by a transparency of at least 90%.

In an embodiment, a distance between the plurality of photovoltaic strips and the concentrator member is associated with a concentration ratio.

In an embodiment, a distance between the plurality of photovoltaic strips and the concentrator member is associated with a concentration ratio of at least 2.

In an embodiment, each of the concentrator strips is characterized by a radius of between 2 mm to 4 mm.

In an embodiment, each of the concentrator strips is characterized by a radius of between 3 mm to 3.3 mm.

In an embodiment, each of the concentrator strips comprises a flat region, the flat region being characterized by a width of less than 1 mm.

In an embodiment, each of the concentrator strips comprises a flat region, the flat region being characterized by a width of less than 0.6 mm.

According to another embodiment, the present invention provides solar concentrator device. The device includes a first surface. The device also includes a second surface. The first surface and the second surface are positioned on opposite sides of the concentrator member. The first surface is substantially flat. The second surface includes a concentrator region and a two edge regions. The concentrator region is positioned between the two edge regions. The concentrator region includes a plurality of concentrator strips. The plurality of concentrator strips is aligned according to the predefined pattern. Each of the concentrator strip is characterized by a substantially semi-cylindrical shape and a radius of less than 5 mm. Each of the concentrator strip is positioned over a predetermined photovoltaic strip. The two edge regions include a first edge member and a second edge member. The first edge member includes a curved region connected to a first concentrator strip. The first edge member further includes a flat region of at least 6 mm. The device includes a thickness of glass material at least 4 mm between the first surface and the second surface. The glass material is characterized by a transparency of at least 90%. In an embodiment, the flat region is least 10 mm. In an embodiment, the radius is between 2.5 mm to 3.5 mm.

According to yet another embodiment, the present invention provides a method for manufacturing a solar panel. The method includes providing a substrate. The method also includes providing a plurality of photovoltaic strips. The method further includes aligning the plurality of photovoltaic strips according to a predefined pattern. The method also includes forming one or more photovoltaic packages by coupling two or more photovoltaic strips using one or more buses. Additionally, the method includes providing a concentrator member comprising a first surface and a second surface. The first surface and the second surface are positioned on opposite sides of the concentrator member. The first surface is substantially flat. The concentrator member comprises a thickness of at least 4 mm between the first surface and the second surface. The second surface includes a concentrator region and a two edge regions. The concentrator region is positioned between the two edge regions. The two edge regions comprise a first edge member and a second edge member. The concentrator region comprises a plurality of concentrator strips. The plurality of concentrator strips is aligned according to the predefined pattern. Each of the concentrator strips is characterized by a substantially semi-cylindrical shape and a radius of less than 5 mm. The first edge member includes a curved region connected to a first concentrator strip. The first edge member further includes a flat region of at least 6 mm. The method also includes aligning concentrator strip to the one or more photovoltaic packages. The method also includes securing the one or more photovoltaic packages to the concentrator member.

In an embodiment, the method further includes forming coupling the photovoltaic packages to the substrate using a holding material.

In an embodiment, the concentrator member consists essentially of glass material.

In an embodiment, the method also includes securing the concentrator member to a frame.

In an embodiment, the method also includes slicing a shape glass sheet to form the concentrator member.

In an embodiment, the method also includes electrically coupling the one or more buses to the photovoltaic packages.

In an embodiment, the method further includes providing a junction box and coupling the one or more buses to the junction box.

Many benefits can be achieved by ways of the present invention. For example, the present solar module provides an assembly system for a manufacturing process. Among other features, assembly systems according to the present invention makes it easier to manufacture, transport, and/or store partially processed solar panels. For example, partially processes photovoltaic assembles comprising multiple photovoltaic strips can be aligned and secured onto an assembly according to the present invention. In certain embodiments, assembly systems are adjustable and flexible, thereby capable of accommodating different types of concentrator structures or photovoltaic assemblies. Additionally, various embodiments according to the present invention are compatible with conventional equipment. There are other benefits as well.

A further understanding of the nature and advantages of the present invention may be realized by reference to the remaining portions of the specification and the drawings.

### BRIEF DESCRIPTION OF THE DRAWINGS

FIG. 1 is a simplified diagram illustrating a concentrated photovoltaic module according to an embodiment of the invention.

FIG. 2 is a simplified diagram illustrating a photovoltaic device.

FIG. 3 is a simplified diagram illustrating photovoltaic assemblies according to an embodiment of the present invention.

FIG. 4 is a simplified diagram illustrating a concentrator member 401 according to an embodiment of the invention.

FIG. 5 is a simplified diagram providing a view to the concentrator member 501 according to an embodiment of the invention.

FIG. 6 is a simplified diagram illustrating dimension of concentrator elements for a concentrator module according to an embodiment of the present invention.

FIG. 7 is a simplified diagram illustrating the side view of a concentrator member according to an embodiment of the present invention.

### DETAILED DESCRIPTION OF THE INVENTION

The present invention is directed to solar energies. More specifically, various embodiments of the present invention provide a shaped concentrator member that is used as a part of concentrated solar panel. The shaped concentrator member includes semi-cylindrically shaped concentrator elements arranged and spaced in parallel to one another. At the edges of the shaped concentrator member, there are flat edge regions that include flat surfaces. In certain embodiments, the shaped concentrator member is used as a part of frameless solar module. There are other embodiments as well.

Embodiments of the present invention provide system and methods for manufacturing concentrated solar panels. Embodiments of the present invention use concentrator elements to reduce the amount of photovoltaic material required, thereby reducing overall cost. It is noted that specific embodiments are shown for illustrative purposes, and represent examples. One skilled in the art would recognize other variations, modifications, and alternatives.

According to embodiments of the present invention, a concentrated solar module comprises a concentrator member, which includes a number of concentrator strips arranged in parallel. A number of small sized photovoltaic cells, each having a number of photovoltaic strips connected by one or more buses, are assemble into a large photovoltaic package that contains photovoltaic strips aligned against the concentrators strips. As described below, embodiments of the present invention provides adjustable assembly system for assembling and integrating photovoltaic cells.

Although orientation is not a part of the invention, it is convenient to recognize that a solar module has a side that faces the sun when the module is in use, and an opposite side that faces away from the sun. Although, the module can exist in any orientation, it is convenient to refer to an orientation where “upper” or “top” refer to the sun-facing side and “lower” or “bottom” refer to the opposite side. Thus an element that is said to overlie another element will be closer to the “upper” side than the element it overlies.

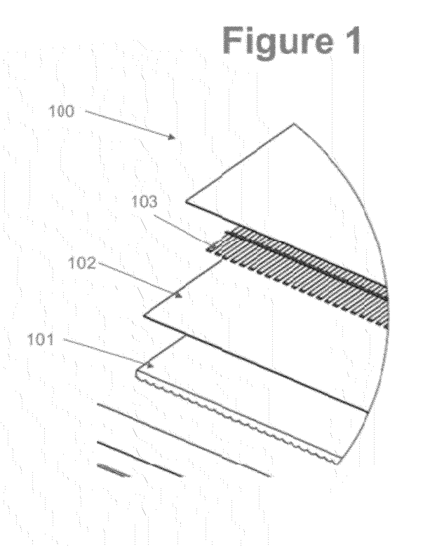

FIG. 1 is a simplified diagram illustrating a concentrated photovoltaic module according to an embodiment of the invention. This diagram is merely an example, which should not unduly limit the scope of the claims. One of ordinary skill in the art would recognize many variations, alternatives, and modifications. As shown in FIG. 1, a photovoltaic module 100 includes a concentrator member 101 that includes a number of concentrator strips that are aligned against the photovoltaic strips of the photovoltaic package 103. For example, the photovoltaic module shown in FIG. 1 is described in U.S. patent application Ser. No. 12/709,438, filed Feb. 19, 2010, and U.S. Provisional Patent Application 61/300,434, filed Feb. 1, 2010, both of which are herein incorporated by reference for all purposes.

In various embodiments, the concentrator member 101 is formed with a plurality of elongated concentrator elements (sometimes referred to as lens elements) that extend along the longitudinal direction of the photovoltaic strips. For at least those embodiments where the concentrator elements lie in a common plane, their center-to-center spacing is nominally equal to that of the photovoltaic strips. For example, the spacing and/or size of photovoltaic strips depend on the desired concentration ratio. Each concentrator element extends longitudinally along the direction of a given strip and transversely across the direction of the strips. A given concentrator element is formed so that parallel light incident on the top surface of the concentrator element, when it reaches the plane of the underlying photovoltaic strip, is confined to a region that has a transverse dimension that is smaller than that of the concentrator element, and possibly also smaller than that of the photovoltaic strip. In the illustrated embodiments, the concentration occurs at the upper surface, although it is also possible to have the concentration occur at the lower surface of the concentrator. Indeed, as in the case of normal lenses, it is possible to have both surfaces provide concentration.

It is common to refer to the concentrator element as providing magnification, since the photovoltaic strip, when viewed through the concentrator element, appears wider than it is. Put another way, when viewed through the concentrator element, the photovoltaic strip preferably fills the concentrator element aperture. Thus, from the point of view of incoming sunlight, the solar module appears to have photovoltaic material across its entire lateral extent.

Although the term magnification is used, it is used in the sense of how much the light is concentrated, and so could equally be referred to as concentration. The magnification/concentration is also sometimes defined as the amount of photovoltaic material saved, and that number is typically less than the optical magnification/concentration since the photovoltaic strips will normally a slightly wider than the width of the light, especially to capture light incident at different angles. The term magnification will typically be used.

The portion of the surface of the concentrator element that provides the magnification has a cross section that can include one or more circular, elliptical, parabolic, or straight segments, or a combination of such shapes. Even though portions of the magnifying (typically upper) surface of the concentrator elements can be flat, it is convenient to think of, and refer to, the magnifying surface as convex, i.e., curved or arch-like. For embodiments where the cross section is semicircular, the surface of the magnifying portion of the concentrator element is semi-cylindrical. However, circular arcs subtending less than 180° are typically used. Although the convex surfaces were referred to as “annular” portions in the above-cited U.S. Patent Application No. 61/154,357, the “annular” nomenclature will not be used here. In some embodiments, the concentrator structure is extruded glass, although other fabrication techniques (e.g., molding) and other materials (e.g., polymers) can be used.

Depending on the application, the photovoltaic module illustrated in FIG. 1 may or not have a frame member encasing the substrate and the concentrator member. In a preferred embodiment, edges of concentrator member 101 comprise flat regions are free from concentrator elements. Detailed description of flat regions is provided below. For example, a machining process is performed to form the concentrator member 101, where the glass material of the concentrator member 101 is machined around the edges. As a result, compared to other regions of the concentrator member 101, there are typically fewer micro cracks (e.g., cracks that may later develop into large cracks) or the like around the edge regions. The added strength at the edge regions of the concentrator member 101 makes it possible to use the concentrator member 101 in the photovoltaic module without the need for a frame securing the concentrator member 101. In contrast, without the flat regions at the edges of the concentrator member 101, it may be necessary for the photovoltaic module to have a frame to secure the concentrator member 101 and provide support.

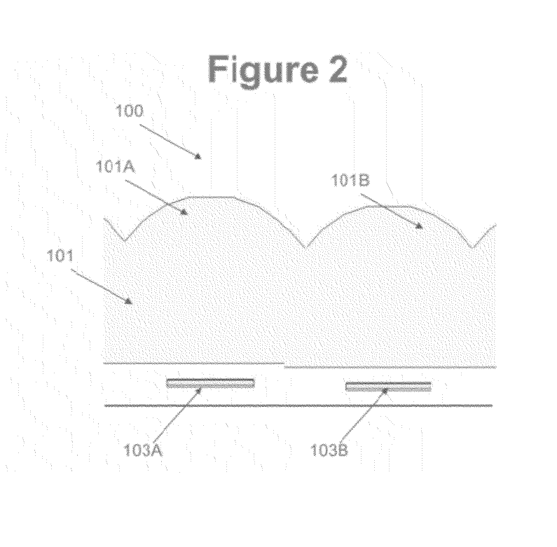

FIG. 2 is a simplified diagram illustrating a photovoltaic device. This diagram is merely an example, which should not unduly limit the scope of the claims. One of ordinary skill in the art would recognize many variations, alternatives, and modifications. A side view of photovoltaic module 100 shown in FIG. 2 includes concentrators 101A and 101B. As an example, the photovoltaic strips 103A and 103B are a part of a photovoltaic assembly and coupled to each other by a bus. As seen from FIG. 2, the photovoltaic strips 103A and 103B are respectively aligned against the concentrators 101A and 101B. For example, the concentrator 101A needs to be aligned to a position essentially directly above the photovoltaic strip 103A so that light from the concentrator 101A can be properly directed to the photovoltaic strip 103A. In various portions of the present applications, concentrator member and concentrator module refer to a piece of material that includes a number of concentrators, concentrator strips, or concentrator elements. That is, the concentrator member 101 includes concentrators 101A and 101B. For example, concentrator strips are cylindrically shaped optical devices that concentrated light onto photovoltaic materials.

In various manufacturing processes, the concentrator member 101 may not be perfectly aligned or evenly spaced during to manufacturing variations. For example, the concentrator member 101 consists of a large piece of glass material that contains multiple concentrator strips (e.g., concentrators 101A and 101B). Each of the concentrator strips functions as a concentrating lens that focus light to a strip of photovoltaic material. Typically, it's easier to align concentrator and photovoltaic strips by adjusting alignment and/or placement of photovoltaic strips. For example, photovoltaic strips 103A and 103B can be moved closer or further apart based on the positions of concentrators 101A and 101B.

Typically, the concentrator member 101 has a large area and is in a single-piece construction. Photovoltaic assemblies, on the other hand, are smaller pieces. For example, the photovoltaic module 100 illustrated in FIG. 1 comprises an integrated piece of concentrator member 101 and the photovoltaic package 103 that is assembled from a number of photovoltaic assemblies.

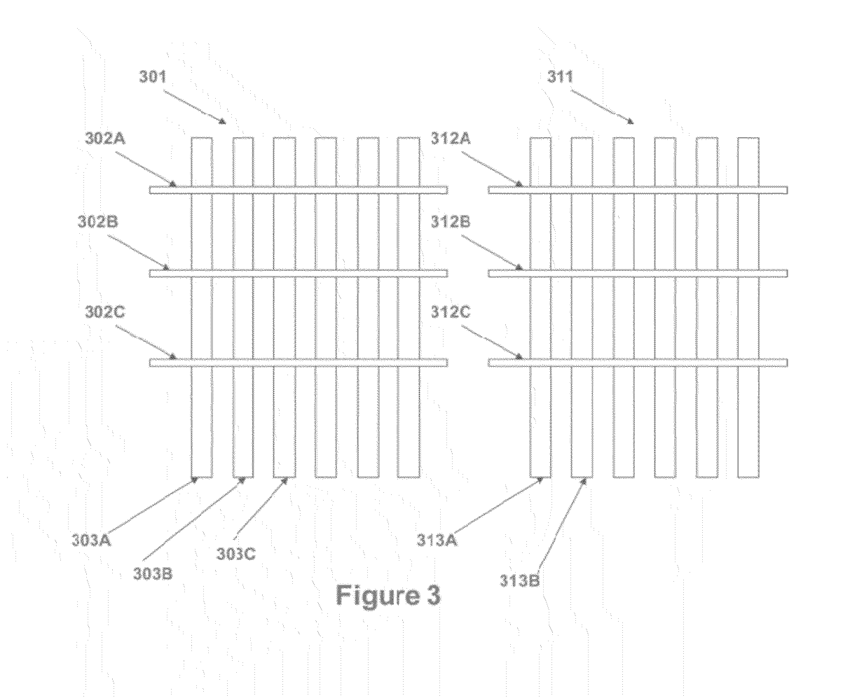

FIG. 3 is a simplified diagram illustrating photovoltaic assemblies according to an embodiment of the present invention. This diagram is merely an example, which should not unduly limit the scope of the claims. One of ordinary skill in the art would recognize many variations, alternatives, and modifications. This diagram is merely an example, which should not unduly limit the scope of the claims. One of ordinary skill in the art would recognize many variations, alternatives, and modifications. As an example, photovoltaic assemblies 301 and 311 are parts of a large photovoltaic package. The photovoltaic assembly 301 includes photovoltaic strips (e.g., strips 303A, 303B, and 303C, etc.) that are coupled to one another by buses 302A, 302B, and 302C. Similarly, photovoltaic assembly 311 includes a photovoltaic strips (e.g., strips 313A, 313B, etc.) that are coupled by buses 312A, 312B, and 313C. For example, the buses comprise electrically conductive material (e.g., metal material). It is to be appreciated that photovoltaic strips, which are typically made of silicon type of material, are often fragile. Thus smaller photovoltaic assemblies 301 and 311 are made and then connected together to form a large photovoltaic package. To connect photovoltaic assemblies 301 and 311, buses are connected. For example, buses 302A, 302B, and 302C are respectively connected to the buses 312A, 312B, and 312C. In an embodiment, a distance between the assemblies 301 and 311 when connected is based on the alignment of the concentrator member.

During the manufacturing process, which typically involves using one or more assembly lines, it is desirable to secure photovoltaic assemblies (e.g., photovoltaic assemblies 301 and 302) onto an assembly system. It is to be appreciated that in various embodiments of the invention, a system is provided to secure photovoltaic assemblies for manufacturing, storage, transporting, and others.

As shown in FIG. 2, the concentrator elements are substantially similar in shape and size. Among other features, the aperture regions (e.g., surfaces that face the light source) is curved at a predetermined radius. More specifically, the curvature and arrangement of the concentrator elements are specifically configured according to the arrangement and size of the photovoltaic strips. For example, a concentrated solar module according to embodiments of the present invention includes the same number of cylindrical concentrator elements as photovoltaic arrays.

As shown in FIGS. 1-3, concentrator elements are aligned in parallel to one another. In a preferred embodiment, size and shape of each concentrator element are substantially identical, and the concentrator elements are formed in the same process. For example, concentrator elements are formed on a single piece of glass ribbon, and together the concentrator elements form a concentrator member. Depending on the application, concentrator elements may be formed by a molding process.

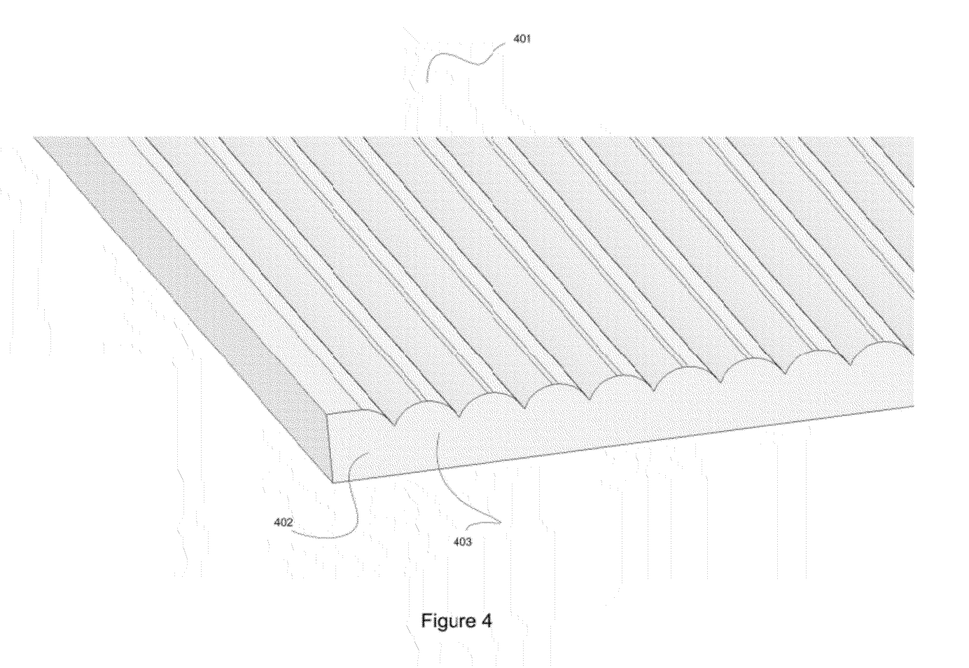

For a concentrator member where concentrator elements are integrated onto a single piece material, such as glass, it is desirable to have flat edges regions. FIG. 4 is a simplified diagram illustrating a concentrator member 401 according to an embodiment of the invention. This diagram is merely an example, which should not unduly limit the scope of the claims. One of ordinary skill in the art would recognize many variations, alternatives, and modifications. A flat edge 402 is arranged in parallel to the length of concentrator elements. The flat edge 402 is positioned in parallel and adjacent to the concentrator element 403. In various embodiments, the flat region of the flat edge 402 is at the same height as the flat top of the concentrator element 403.

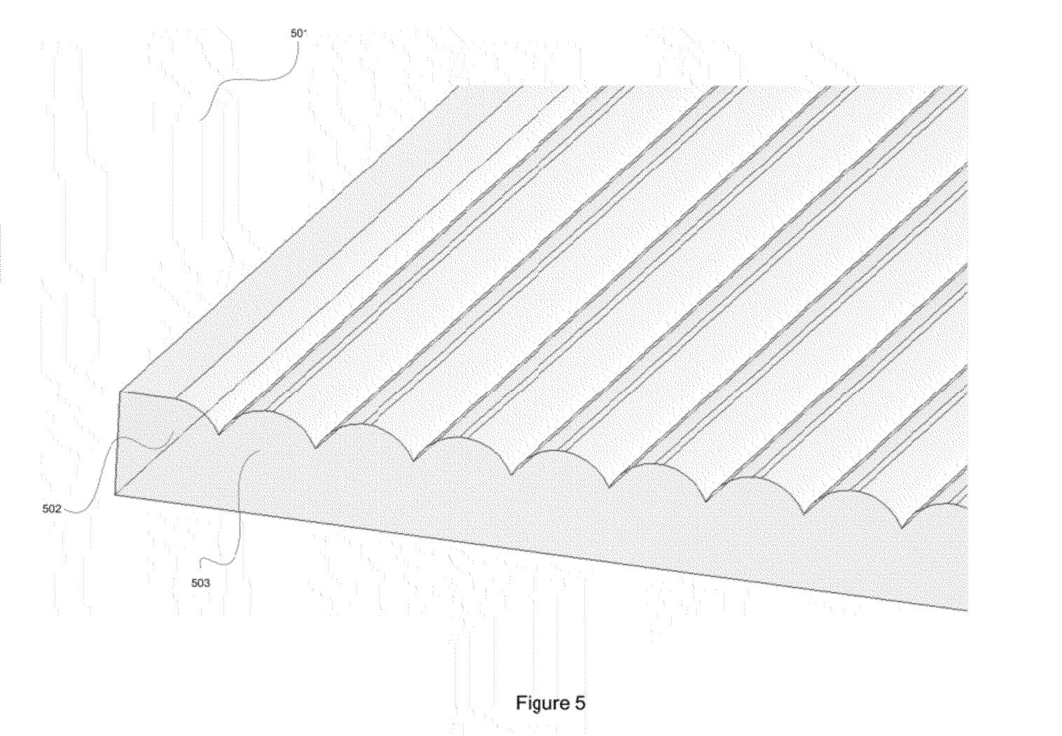

FIG. 5 is a simplified diagram providing a view to the concentrator member 501 according to an embodiment of the invention. This diagram is merely an example, which should not unduly limit the scope of the claims. One of ordinary skill in the art would recognize many variations, alternatives, and modifications. As shown in FIG. 5, the flat edge 502 is adjacent to the concentrator element 503. A part of the flat 502 is curved. For example, the curvature of the flat edge 502 is characterized by the same radius of curvature as the concentrator element 503.

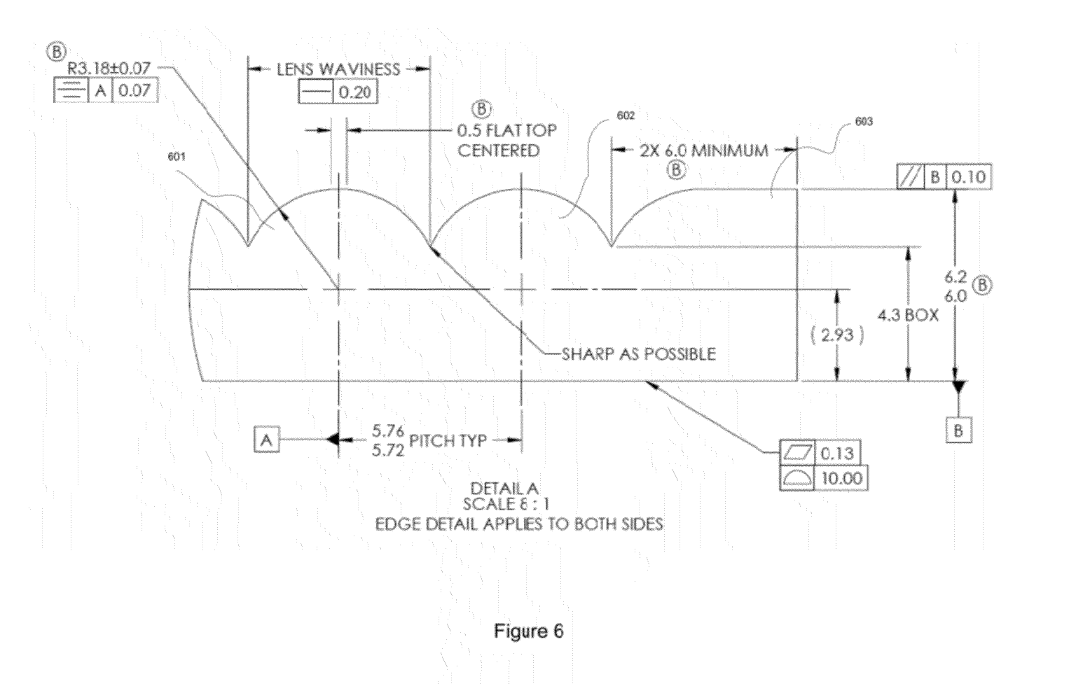

FIG. 6 is a simplified diagram illustrating dimension of concentrator elements for a concentrator module according to an embodiment of the present invention. This diagram is merely an example, which should not unduly limit the scope of the claims. One of ordinary skill in the art would recognize many variations, alternatives, and modifications. As shown in FIG. 6, concentrator elements 601 and 602 are adjacent to each other and have substantially the same shape. The curved regions of the concentrator elements are characterized by a curvature radius of about 3.18 mm. Each of the concentrator elements comprises a top flat region. For example, the flat region can be about 0.5 mm. The thickness between the top flat region and bottom of a concentrator element is about 6 mm. Among other things, the radius of curvature and the size of the top flat region of concentrator elements are specifically designed to efficiently concentrate light onto photovoltaic strips.

The concentrator element 602 is positioned next to the edge element 603. As shown, the edge element 603 comprises a curve region and a flat region. The curve region is next to the concentrator element 602. Depending on the application, the flat region of the edge element 603 can be 10 mm or greater. The thickness between flat region and the bottom of the edge element 603 is about 6 mm.

It is to be appreciated that the shape and dimensions illustrated in FIG. 6 and described above can be varied. For example, the dimension of the flat region, radius of curvature, size of the flat region, and other dimensions can be varied. In certain embodiments, the thickness of the concentrator member illustrated in FIG. 6 is associated with a desired concentration ratio. For example, a higher concentration ratio can be achieved by increasing the thickness, thereby increasing the distance from concentrator element to photovoltaic strips.

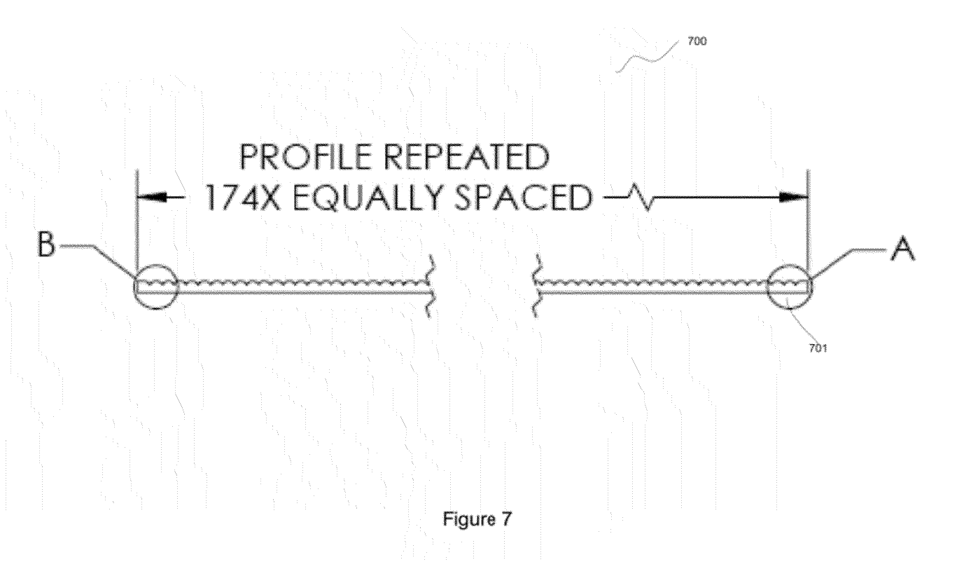

FIG. 7 is a simplified diagram illustrating the side view of a concentrator member according to an embodiment of the present invention. This diagram is merely an example, which should not unduly limit the scope of the claims. One of ordinary skill in the art would recognize many variations, alternatives, and modifications. As shown in FIG. 7, a concentrator member 700 includes 174 substantially equally spaced concentrator elements. The concentrator member 700 includes two flat edges, at its two ends. As an example, the portion 701 of the concentrator member 700 is illustrated in FIG. 6. It is to be appreciated that the concentrator member may include a different number of concentrator elements, and the concentrator elements may have different shape and/or sizes.

It is to be appreciated that the flat edges of the concentrator member provides numerous benefits. Among other things, the concentrator member that is flat on both top side and the bottom side around the edge area is easier to edge during the manufacturing process. For example, the flat edge can be formed by sanding, grinding, polishing, and/or other processes. In various embodiments, flat region of the edge area formed by polishing area provides better yield during the manufacturing compared to concentrator member without the flat region. For example, without the flat region, there are sometimes nibs or points of stress concentration. When tempered, assembled to, or framed, these nibs or points of stress can act as stress concentrators that cause a complete glass or concentrator member failure. Additionally, to form glass concentrator member with flat edge, the edge can be shaped by belt sander, grinding well, polishing wheel, and other types of tools. In contrast, if edge of the concentrator member does not have flat edges but have cylindrical shaped concentrators at the edges instead, putting edge and/or frame around the edge of the concentrator member becomes very difficult, as curved surfaces are hard to work with. In various embodiments, the flat region for each of the flat edge is at least 12 mm. When concentrator elements are stacked on top of one another for storage, the relative large area of the flat region at the edge of the concentrator allows weight to be evenly distributed, thereby reducing the likelihood of concentrator element cracking. As illustrated in FIGS. 4 and 5, that top flat region of the concentrator strip is about the same level as the flat region of the flat edge area. For example, in FIG. 4 the concentrator element 403 comprises a flat top, which is at approximately the same height as the flat edge 402. When the concentrator member is mounted or stacked, the “flat surfaces” of concentrator elements and the concentrator share the weight.

As mentioned above, the concentrator module consists essentially of glass material. For example, a concentrator module may have a dimension about 1610 mm by 1610 mm by 6 mm. The 6 mm of thickness of a glass material with concentrators can be prone to cracking or other damages. The flat regions at the edge regions improves the strength and reliability of concentrator module.

In various embodiments, the concentrator member, as a part of the solar module, is attached to a frame. The flat region at the edge area of the concentrator member makes it easier to attach the concentrator member to the frame. That is because the contact area between the frame and the concentrator member is typically flat. Having a relatively large flat region at the edge thus means large area of contact with the frame and/or adhesive material. In a preferred embodiment, the flat tops of the concentrator elements and the flat edge are level, thereby making the thickness of the concentrator module substantially uniform.

The flat edge for the concentrator member can be manufacturing in various ways, as described below. In various embodiments, the concentrator module is formed from a large piece of glass ribbon. The parallel concentrator strips are formed by a molding processes, in which a large piece of glass ribbon is molded. The flat edges of the concentrator module can be formed by sanding, grinding, polishing, and/or other process. In certain cases, if the glass ribbon is large enough, the flat regions at the edges allow natural edge corner (with slight curve) to form.

In various embodiments, concentrator members are manufacturing in a processes compatible with convention glass manufacturing equipments. In a preferred embodiments, low iron glass with transparency of at least 90% are used as concentrator material. Concentrator modules are manufactured as shaped glass ribbon, where concentrator elements are formed by a molding process. Typically, rolling type of molding equipment is used for forming substantially a same shape and/or pattern. To form both cylindrical shaped lens as concentrator elements and flat edges, specially formed mold is used. More specifically, specialized molds used in manufacturing concentrator members is specifically designed to form concentrator pattern, flat edge, and transitions thereof. For example, two types of molds are used; one type of mold is used to form cylindrical lens pattern for concentrator element, and another type of mold with slightly different shape is used to form concentrator edges that has both curve regions and flat regions.

In certain embodiments, two or more pieces of concentrator member are manufactured from a single piece of glass ribbon. Before separation, two adjacent concentrator members are separated by a flat region. When these two adjacent concentrator members are separated from each other, the flat region formerly separating the two concentrator members forms flat edges for the concentrator members.

According to an embodiment, a solar module 100 (illustrated in FIG. 1) is manufactured according to the following steps:

1. providing a substrate;

2. providing a plurality of photovoltaic strips;

2. aligning the plurality of photovoltaic strips according to a predefined patterns;

3. forming one or more photovoltaic packages by coupling two or more photovoltaic strips using one or more buses;

4. providing a concentrator member aligning concentrator strip to the one or more photovoltaic packages;

5. securing the one or more photovoltaic packages to the concentrator member; and

6. securing the photovoltaic packages and the concentrator member to a frame.

As explained above, the substrate can be made of various types of materials, such as polymeric material and others. As an example, the photovoltaic strips and their alignment is illustrated in FIG. 3 and described above. For example, the concentrator member used is the concentrator member 101 illustrated in FIG. 1 and described above. Among other things, the concentrator member comprises a first surface and a second surface. The first surface and the second surface are positioned on opposite sides of the concentrator member. The first surface is substantially flat. The concentrator member comprises a thickness of at least 6 mm between the first surface and the second surface. The second surface comprises a concentrator region and a two edge regions. The concentrator region is positioned between the two edge regions. For example, the concentrator region comprises 174 concentrator elements as illustrated in FIG. 7. The two edge regions comprise a first edge member and a second edge member. The concentrator region comprises a plurality of concentrator strips. For example, the concentrator strips are cylindrical optical lenses that are specifically configured to concentrate light onto photovoltaic strips. The plurality of concentrator strips is aligned according to the predefined pattern (e.g., as shown in FIG. 3). Each of the concentrator strip is characterized by a substantially semi-cylindrical shape and a radius of less than 5 mm. The first edge member comprises a curved region connected to a first concentrator strip. For example, the edge member and the concentrator strip are illustrated in FIG. 6. The first edge member further includes a flat region of at least 10 mm.

It is to be understood that various steps described above can be added, removed, replaced, modified, re-arranged, repeated, and/or overlapped, and they should not unduly limit the scope of claims.

While the above is a complete description of specific embodiments of the invention, the above description should not be taken as limiting the scope of the invention as defined by the claims.

What is claimed is:

1. A solar panel device comprising:
a substrate member;
a plurality of photovoltaic strips overlaying the substrate member, the plurality of photovoltaic strips being aligned according to a predefined pattern, each of the photovoltaic strips being derived from a dicing process from a silicon based solar cell, the silicon based solar cell being a functional solar cell;
a bus electrically coupling two or more photovoltaic strips;
a concentrator member overlaying the plurality of photovoltaic strips, the concentrator member comprising a first surface and a second surface, the first surface and the second surface being positioned on opposite sides of the concentrator member, the first surface being substantially flat, the concentrator member comprising a thickness of at least 4 mm between the first surface and the second surface, the second surface comprising a concentrator region and two edge regions, the concentrator region being positioned between the two edge regions, the concentrator region comprising a plurality of concentrator strips, the plurality of concentrator strips being aligned according to the predefined pattern, each of the concentrator strips being characterized by a substantially semi-cylindrical shape and a radius of less than 5 mm, each of the concentrator strip being positioned over a predetermined photovoltaic strip, the two edge regions comprising a first edge member and a second edge member, the first edge member comprising a curved region connected to a first concentrator strip, the curved region and the first concentrator strip being separated by a notch, the first edge member further comprising a flat region of at least 6 mm;
whereupon the flat region configured with a predetermined height substantially even with an upper region of each of the plurality of concentrator strips such that the flat region serves as a mechanical support for one or more other regions; and
whereupon the flat region is configured to provide the mechanical support while maintaining a desirable aperture characteristic of the concentrator region.

2. The device of claim 1 wherein the concentrator strips each comprises a top flat region, the top flat region being leveled against the flat region of the first concentrator strip.

3. The device of claim 1 wherein the concentrator member is characterized by a substantially square shape.

4. The device of claim 1 further comprising a frame member coupled to the flat region of the first edge member.

5. The device of claim 1 wherein:
the concentrator member is free from sharp edges;
a portion of the flat region is polished.

6. The device of claim 1 wherein the concentrator member comprises at least 150 concentrator strips.

7. The device of claim 1 wherein each of the concentrator strip is aligned to direct light to at least two photovoltaic strips.

8. The device of claim 1 wherein the concentrator strips are evenly spaced.

9. The device of claim 1 wherein the concentrator member consists essentially of glass material.

10. The device of claim 1 wherein the concentrator member comprises a transparent material characterized by a transparency of at least 90%.

11. The device of claim 1 wherein a distance between the plurality of photovoltaic strips and the concentrator member is associated with a concentration ratio.

12. The device of claim 1 wherein each of the concentrator strips is characterized by a radius of between 3 mm to 3.3 mm.

13. The device of claim 1 wherein each of the concentrator strips comprises a flat region, the flat region being characterized by a width of less than 1 mm.

14. A solar concentrator device comprising:
a first surface;
a second surface, the first surface and the second surface being positioned on opposite sides of the concentrator member, the first surface being substantially flat, the second surface comprising a concentrator region and a two edge regions, the concentrator region being positioned between the two edge regions, the concentrator region comprising a plurality of concentrator strips, the plurality of concentrator strips being aligned according to the predefined pattern, each of the concentrator strip being characterized by a substantially semi-cylindrical shape and a radius of less than 5 mm, each of the concentrator strip being positioned over a predetermined photovoltaic strip, the two edge regions comprising a first edge member and a second edge member, the first edge member comprising a curved region connected to a first concentrator strip, first edge member further comprising a flat region of at least 6 mm, the first region being adapted to gluing to a frame member of a solar panel;
a thickness of glass material at least 4 mm between the first surface and the second surface, the glass material being characterized by a transparency of at least 90%;
whereupon the flat region is configured with a predetermined height substantially even with an upper region of each of the plurality of concentrator strips such that the flat region serves as a mechanical support for one or more other regions; and
whereupon the flat region is configured to provide the mechanical support while maintaining a desirable aperture characteristic of the concentrator region.

15. A method for manufacturing a solar panel, the method comprising:
providing a substrate;
providing a plurality of photovoltaic strips;
aligning the plurality of photovoltaic strips according to a predefined patterns;
forming one or more photovoltaic packages by coupling two or more photovoltaic strips using one or more buses;
forming a concentrator member comprising a first surface and a second surface, the first surface and the second surface being positioned on opposite sides of the concentrator member, the first surface being substantially flat, the concentrator member comprising a thickness of at least 4 mm between the first surface and the second surface, the second surface comprising a concentrator region and a two edge regions, the concentrator region being positioned between the two edge regions, the two edge regions comprising a first edge member and a second edge member, the concentrator region comprising a plurality of concentrator strips, the plurality of concentrator strips being aligned according to the predefined pattern, each of the concentrator strip being characterized by a substantially semi-cylindrical shape and a radius of less than 5 mm, the first edge member comprising a curved region connected to a first concentrator strip, first edge member further comprising a flat region of at least 6 mm, flat region being configured with a predetermined height substantially even with an upper region of each of the plurality of concentrator strips such that the flat region serves as a mechanical support for one or more other regions;
aligning concentrator strip to the one or more photovoltaic packages; and
securing the one or more photovoltaic packages to the concentrator member.

16. The method of claim 15 wherein the concentrator member consists essentially of glass material.

17. The method of claim 15 further comprising:
providing a frame member, the frame member having a bonding region;
providing an adhesive material;
form a coupling region by gluing the flat region to the bonding region.

18. The method of claim 15 further comprising slicing a shared region of the shaped glass sheet to form the concentrator member, the flat region of the first edge being a portion of the shared region.

19. The method of claim 15 further comprising electrically coupling the one or more buses to the photovoltaic packages.

20. The method of claim 15 further comprising:
providing a junction box;
coupling the one or more buses to the junction box;
